(19) United States
(12) Patent Application Publication
(10) Pub. No.: US 2026/0214914 A1
(43) Pub. Date: Jul. 23, 2026

(54) SEMICONDUCTOR MEMORY MODULE

(71) Applicant: SAMSUNG ELECTRONICS CO., LTD., Suwon-si (KR)

(72) Inventors: KI-HONG JEONG, Suwon-si (KR); HONGJIN KIM, Suwon-si (KR); SANG SUB SONG, Suwon-si (KR)

(73) Assignee: SAMSUNG ELECTRONICS CO., LTD., Suwon-si (KR)

(21) Appl. No.: 19/304,154

(22) Filed: Aug. 19, 2025

(30) Foreign Application Priority Data
Jan. 21, 2025 (KR) 10-2025-0008686

(51) Int. Cl. H10B 80/00; H01L 25/00; H01L 25/065; H01L 25/11

(52) U.S. Cl. CPC H10B 80/00; H10W 90/00; H10W 70/60; H10W 90/24; H10W 90/291; H10W 90/722; H10W 90/752; H10W 90/754

(57) ABSTRACT

A semiconductor memory module includes a substrate including a first side and a second side opposing the first side, a first semiconductor package on the first side, the first semiconductor package including a first bottom surface facing the first side, and first signal connection balls between the first side and the first bottom surface. The first bottom surface includes a first subdivision surface, and a second subdivision surface divided from the first subdivision surface based on a horizontal line extending in a first direction, and the first signal connection balls on the first subdivision surface and the first signal connection balls on the second subdivision surface are arranged symmetrically with each other with respect to the horizontal line.

### CROSS-REFERENCE TO RELATED APPLICATION

This U.S. non-provisional patent application claims priority under 35 U.S.C. §119 of Korean Patent Application No. 10-2025-0008686, filed on Jan. 21, 2025, the entire contents of which being hereby incorporated by reference.

### BACKGROUND

The present disclosure herein relates to a semiconductor memory module.

Many electronic systems include semiconductor memory modules such as a solid state drive (SSD), a dual in-line memory module (DIMM), and a small outline DIMM, and all of those semiconductor memory modules use memory cells for storing data as electric charge or voltage. Storage density of such modules has been improved by increasing the density of memory cells on an individual memory component by using improved manufacturing technology. In addition, the storage density of such modules has been increased by including a larger number of memory components in each memory device or module by using advanced board-level packaging technology.

### SUMMARY

It is an aspect to provide a semiconductor memory module having improved electrical characteristics.

The aspects of the present disclosure are not limited to the above-mentioned aspects, and other aspects not mentioned would be clearly understood by those skilled in the art from the disclosure below.

According to an aspect of one or more embodiments, there is provided a semiconductor memory module comprising a substrate including a first side and a second side opposing the first side; a first semiconductor package on the first side, the first semiconductor package including a first bottom surface facing the first side; and first signal connection balls between the first side and the first bottom surface. The first bottom surface includes a first subdivision surface, and a second subdivision surface divided from the first subdivision surface based on a horizontal line extending in a first direction, and the first signal connection balls on the first subdivision surface and the first signal connection balls on the second subdivision surface are arranged symmetrically with each other with respect to the horizontal line.

According to another aspect of one or more embodiments, there is provided a semiconductor memory module comprising a substrate including a first side a second side opposing the first side; a first semiconductor package on the first side, the first semiconductor package including a first bottom surface facing the first side; and first signal connection balls interposed between the first side and the first bottom surface. The first bottom surface includes a first subdivision surface, and a second subdivision surface that is divided from the first subdivision surface based on a horizontal line extending in a first direction. The first semiconductor package includes a first semiconductor chip and a second semiconductor chip. The first signal connection balls include first channel balls connected to the first semiconductor chip; and second channel balls connected to the second semiconductor chip. The first channel balls on the first subdivision surface are arranged symmetrically with the second channel balls on the second subdivision surface with respect to the horizontal line.

According to yet another aspect of one or more embodiments, there is provided a semiconductor memory module comprising a substrate including a first side and a second side opposing the first side; a first semiconductor package on the first side, the first semiconductor package including a first bottom surface facing the first side; a second semiconductor package on the second side of the substrate, the second semiconductor package including a second bottom surface facing the second side; first signal connection balls interposed between the first side and the first bottom surface; and second signal connection balls interposed between the second side and the second bottom surface. The first bottom surface includes a first subdivision surface and a second subdivision surface that is divided from of the first subdivision surface based on a horizontal line extending in a first direction; and a third subdivision surface divided from the first subdivision surface based on a vertical line extending in a second direction intersecting the first direction. The first signal connection balls on the first subdivision surface and the first signal connection balls on the second subdivision surface are arranged symmetrically with each other with respect to the horizontal line, and the first signal connection balls on the first subdivision surface and the first signal connection balls on the third subdivision surface are arranged symmetrically with each other with respect to the vertical line.

According to still another aspect of one or more embodiments, there is provided a method of manufacturing a semiconductor memory module including forming a first conductive pad on a first side of a module substrate; forming a second conductive pad on a second side of the module substrate, the second side opposing the first side; forming a first semiconductor package on the first side; forming a second semiconductor package on the second side; forming first signal connection balls between the first side and the first semiconductor package; and forming second signal connection balls between the second side and the second semiconductor package, wherein the first semiconductor package includes a first bottom surface facing the first side, the first bottom surface includes a first subdivision surface and a second subdivision surface that is divided from the first subdivision surface based on a horizontal line extending in a first direction, and the forming of the first signal connection balls includes arranging the first signal connection balls on the first subdivision surface and the first signal connection balls on the second subdivision surface symmetrically with each other with respect to the horizontal line.

### BRIEF DESCRIPTION OF THE FIGURES

The above and other aspect may be more clearly understood from the following description taking in conjunction with the drawings, in which:

FIG. 1 is a block diagram illustrating a schematic configuration of a storage system according to embodiments;

FIG. 2 is a plan view of a semiconductor memory module according to embodiments;

FIG. 3 is a cross-sectional view taken along line A-A′ of FIG. 2;

FIG. 4A is a plan view for describing a first semiconductor package of the semiconductor memory module of FIG. 2, according to embodiments;

FIGS. 4B and 4C are plan views for describing the first semiconductor package of the semiconductor memory module of FIG. 2, according to some embodiments; and

FIGS. 5A, 5B, and 5C are cross-sectional views for describing a method of manufacturing a semiconductor memory module, according to embodiments.

### DETAILED DESCRIPTION

Hereinafter, various embodiments will be described in detail with reference to the drawings in order to describe the inventive concept in more detail.

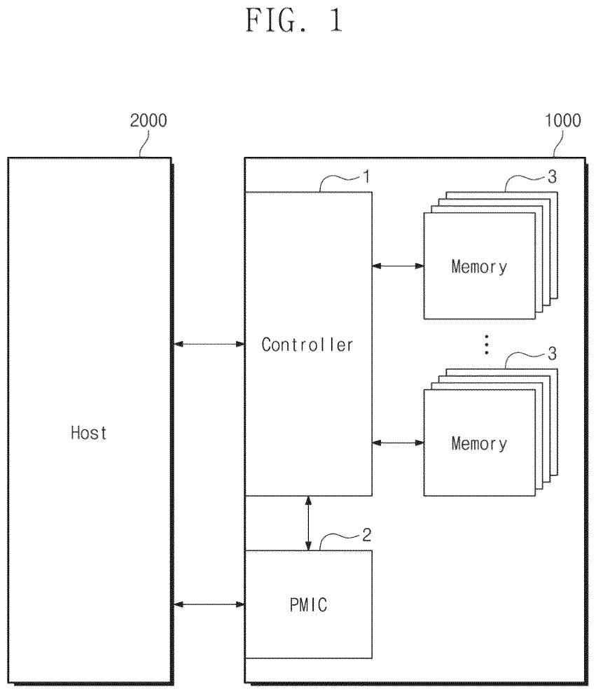

FIG. 1 is a block diagram illustrating a schematic configuration of a storage system, according to embodiments.

Referring to FIG. 1, the storage system may include a host 2000 and a semiconductor memory module 1000. In an embodiment, the host 2000 may be an external device that is external to the semiconductor memory module 1000. The semiconductor memory module 1000 may store or output data in response to a read/write request from the host 2000. For example, the semiconductor memory module 1000 may be a solid state drive (SSD), a dual in-line memory module (DIMM), or a small outline dual in-line memory module (SO-DIMM).

The semiconductor memory module 1000 may include a controller 1, a power management integrated circuit (PMIC) chip 2, and memory packages 3. In some embodiments, the semiconductor memory module 1000 may include an input/output interface (not shown). The memory packages 3 may be used as a storage medium of the semiconductor memory module 1000. In an embodiment, the memory packages 3 may each include a plurality of nonvolatile memory chips.

For example, in some embodiments, the memory packages 3 may be a NAND-type flash memory or a vertical NAND (VNAND) (or 3-dimensional NAND) flash memory chip having large capacity and high-speed storage capacity. In some embodiments, the memory packages 3 may be a phase change random access memory (PRAM), a magnetic random access memory (MRAM), a resistive random access memory (ReRAM), a ferromagnetic random access memory (FRAM), a dynamic random-access memory (DRAM), a NOR flash memory, or the like.

The controller 1 may include a program for exchanging signals with an external device using a method according to, for example, a serial advanced technology attachment (SATA) standard, a parallel advanced technology attachment (PATA) standard, or a small computer system interface (SCSI) standard.

The power management integrated circuit (PMIC) chip 2 may receive power from the host 2000 and supply the power to the controller 1. In an embodiment, the PMIC chip 2 may be located in the semiconductor memory module 1000 as illustrated in FIG. 1. In some embodiments, the PMIC chip 2 may be located outside the semiconductor memory module 1000 unlike the structure illustrated in FIG. 1. For example, the PMIC chip 2 may be located on a main board and provide power to the semiconductor memory module 1000.

In an embodiment, the controller 1, the PMIC chip 2, and the memory packages 3 may be arranged on the same printed circuit board (PCB). In this case, the controller 1, the PMIC chip 2, and the memory packages 3 may be connected to each other through lines formed on the printed circuit board.

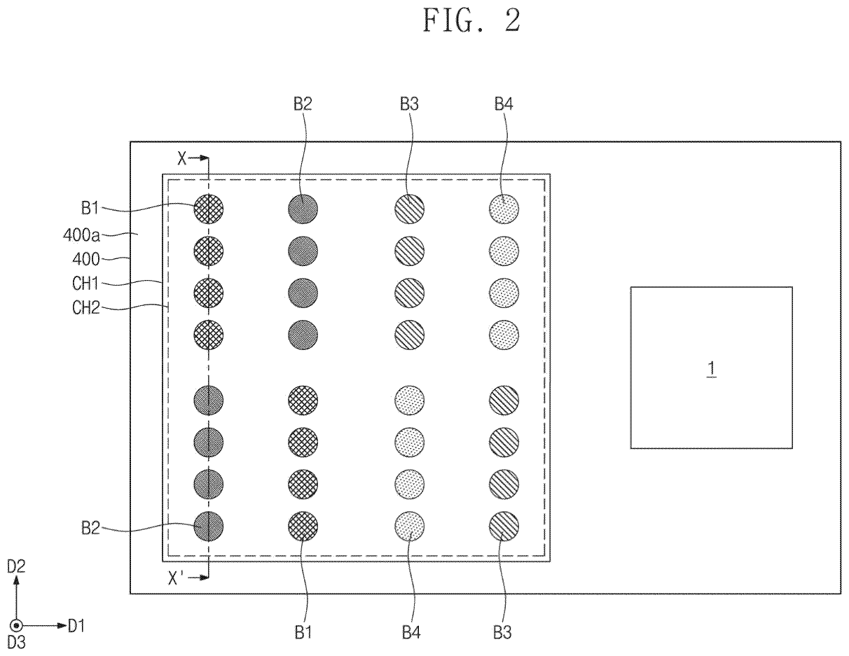

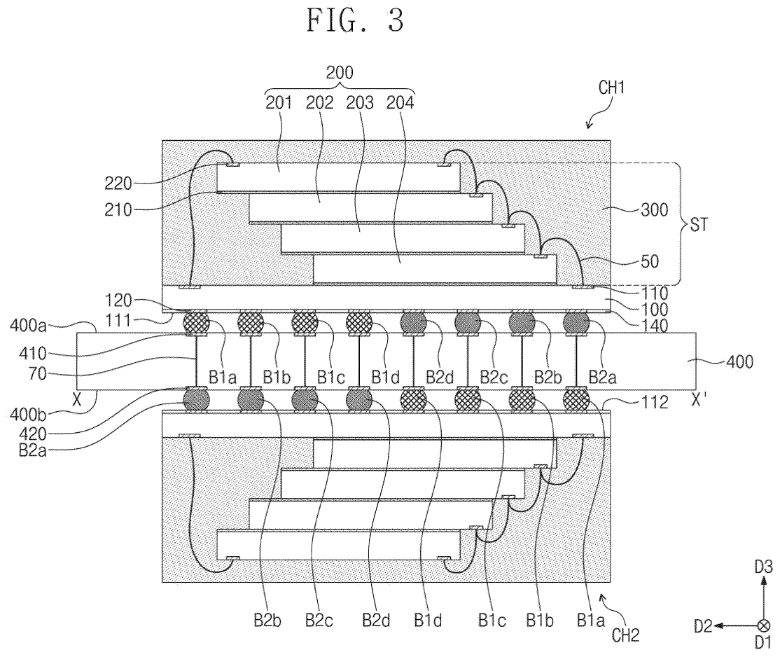

FIG. 2 is a plan view of a semiconductor memory module according to some embodiments. FIG. 3 is a cross-sectional view taken along line A-A′ of FIG. 2.

Referring to FIGS. 2 and 3, the semiconductor memory module may include a module substrate 400. The module substrate 400 may include a first side 400a and a second side 400b opposing the first side 400a. The first side 400a and the second side 400b may extend in a first direction D1. In an embodiment, each of the first side 400a and the second side 400b may be a surface of the module substrate 400 in a plane in the first direction D1 and a second direction D2 that crosses the first direction D1. The module substrate 400 may be, for example, a double-sided or multi-layer printed circuit board.

A first semiconductor package CH1 and a second semiconductor package CH2 may be mounted on the module substrate 400. The first and second semiconductor packages CH1 and CH2 may individually be a flash memory chip, a DRAM chip, an SRAM chip, an EEPROM chip, a PRAM chip, an MRAM chip, an ReRAM chip, a high bandwidth memory (HBM) chip, or a hybrid memory cubit (HMC). In other words, in some embodiments, each of the first and second semiconductor packages CH1 and CH2 may individually be a flash memory chip, a DRAM chip, an SRAM chip, an EEPROM chip, a PRAM chip, an MRAM chip, an ReRAM chip, a high bandwidth memory (HBM) chip, or a hybrid memory cubit (HMC). In some embodiments, the first and second semiconductor packages CH1 and CH2 may individually be a system large scale integration (LSI) chip or a logic circuit chip. In some embodiments, the first and second semiconductor packages CH1 and CH2 may individually be a microelectromechanical system (MEMS) element chip or an application-specific integrated circuit (ASIC) chip.

The first semiconductor package CH1 may be provided on the first side 400a of the module substrate 400. The second semiconductor package CH2 may be provided on the second side 400b of the module substrate 400. Thus, the first semiconductor package CH1 and the second semiconductor package CH2 may be spaced apart from each other in a third direction D3 with the module substrate 400 therebetween. In an embodiment, the third direction D3 may be orthogonal to the first direction D1 and the second direction D2. The first semiconductor package CH1 and the second semiconductor package CH2 may partially overlap each other. For example, the first semiconductor package CH1 and the second semiconductor package CH2 may partially overlap each other in the third direction D3.

First conductive pads 410 may be provided on the first side 400a of the module substrate 400. Second conductive pads 420 may be provided on the second side 400b of the module substrate 400. The first conductive pads 410 and the second conductive pads 420 may include a conductive material. For example, the first conductive pads 410 and the second conductive pads 420 may include at least one metal among copper (Cu), gold (Au), nickel (Ni), tin (Sn), silver (Ag), tungsten (W), and aluminum (Al).

The first and second semiconductor packages CH1 and CH2 may each include a package substrate 100, a stack structure ST, bonding wires 50, and a first molding member 300. The package substrate 100 may include, for example, a printed circuit board, a flexible substrate, a tape substrate, or the like. The package substrate 100 may be a multi-layer circuit board including vias and various circuits therein.

Third conductive pads 110 may be arranged on an upper surface of the package substrate 100. Fourth conductive pads 120 may be arranged on a lower surface of the package substrate 100. The third and fourth conductive pads 110 and 120 may include, for example, at least one metal among copper (Cu), gold (Au), nickel (Ni), tin (Sn), silver (Ag), tungsten (W), and aluminum (Al). A protective layer 140 may cover the lower surface of the package substrate 100 and a sidewall of the fourth conductive pads 120. The protective layer 140 may include at least one of silicon oxide, silicon nitride, or silicon carbon nitride. In some embodiments, the protective layer 140 may expose the fourth conductive pads 120 therethrough.

The stack structure ST may be arranged on the package substrate 100. The stack structure ST may include semiconductor dies 200 sequentially stacked on the package substrate 100. The semiconductor dies 200 may include a first semiconductor chip 201, a second semiconductor chip 202, a third semiconductor chip 203, and a fourth semiconductor chip 204 stacked. Although FIG. 3 illustrates four chips, the number of chips included in the stack structure ST may be various, for example, 8, 16, or 24. The semiconductor dies 200 may include, for example, a nonvolatile memory device such as a NAND flash memory. The semiconductor dies 200 may each include the same type of a semiconductor die.

An adhesive member 210 may be provided between the semiconductor die 200 and the package substrate 100 and between the semiconductor dies 200. The adhesive member 210 may include, for example, a die attach film (DAF) or epoxy resin.

A chip pad 220 may be provided on an upper surface of each of the semiconductor dies 200. The chip pads 220 may include, for example, at least one metal among copper (Cu), gold (Au), nickel (Ni), tin (Sn), silver (Ag), tungsten (W), and aluminum (Al).

The semiconductor dies 200 may be connected to the package substrate 100 using a wire bonding method. For example, the bonding wires 50 may connect the chip pads 220 to the corresponding third conductive pads 110 of the package substrate 100. The bonding wires 50 may include a conductive material.

The first molding member 300 may cover the first substrate 100, the stack structure ST, and the bonding wires 50. The first molding member 300 may include, for example, an insulative resin such as an epoxy molding compound (EMC). The first molding member 300 may further include a filler, which may be dispersed in the insulative resin.

The first semiconductor package CH1 may include a first bottom surface 111 facing the first side 400a of the module substrate 400. First signal connection balls B1 to B4 may be interposed between the first side 400a and the first bottom surface 111. In other words, the first signal connection balls B1 to B4 may be interposed between the first semiconductor package CH1 and the module substrate 400.

The first signal connection balls B1 to B4 may be respectively bonded to the fourth conductive pads 120 of the first semiconductor package CH1. The first signal connection balls B1 to B4 may be respectively arranged on the first conductive pads 410 of the module substrate 400. The first signal connection balls B1 to B4 may connect the first semiconductor package CH1 and the module substrate 400 to each other.

The second semiconductor package CH2 may include a second bottom surface 112 facing the second side 400b of the module substrate 400. Second signal connection balls B1 to B4 may be interposed between the second side 400b and the second bottom surface 112. In other words, the second signal connection balls B1 to B4 may be interposed between the second semiconductor package CH2 and the module substrate 400.

The second signal connection balls B1 to B4 may be respectively bonded to the fourth conductive pads 120 of the second semiconductor package CH2. The second signal connection balls B1 to B4 may be respectively arranged on the second conductive pads 420 of the module substrate 400. The second signal connection balls B1 to B4 may connect the second semiconductor package CH2 and the module substrate 400 to each other.

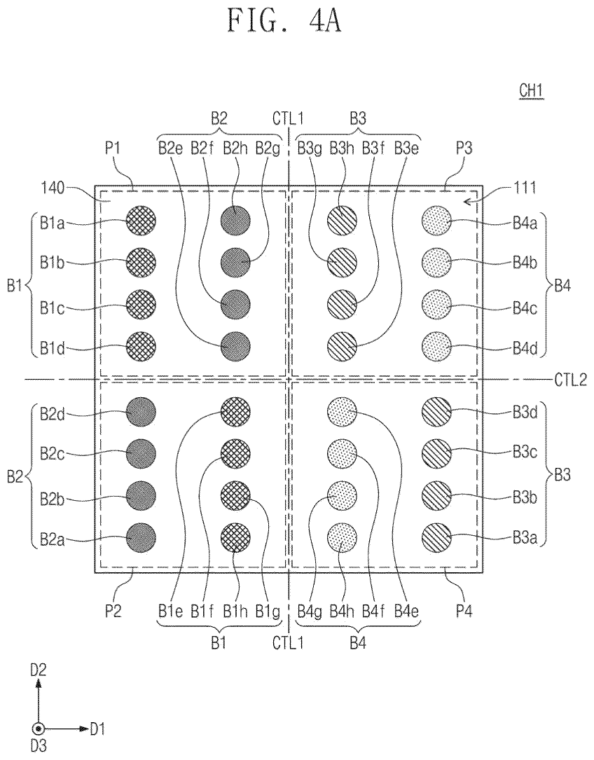

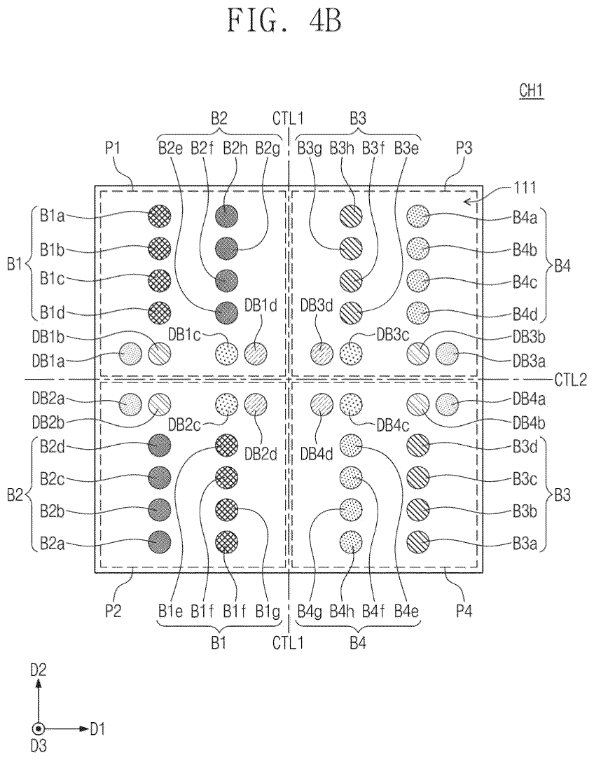

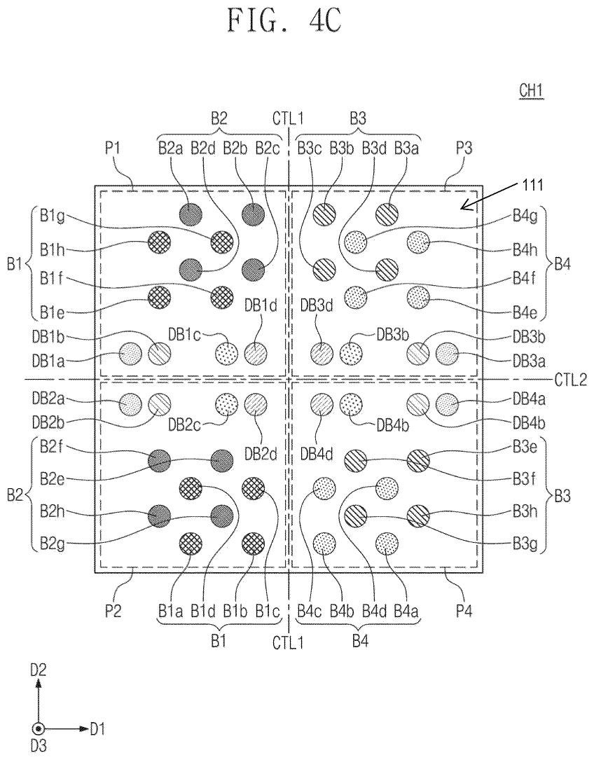

FIG. 4A is a plan view for describing the first semiconductor package of FIG. 2 according to some embodiments. FIG. 4A illustrates a plan view looking from the module substrate 400 toward the first semiconductor package CH1. Referring to FIGS. 3 and 4A, the first and second signal connection balls B1 to B2 will be described in more detail. The following technical features of the first semiconductor package CH1 described with reference to FIG. 4A may be substantially identically applied to the second semiconductor package CH2.

Referring to FIGS. 3 and 4A, the first bottom surface 111 of the first semiconductor package CH1 may include a first subdivision surface P1, a second subdivision surface P2, a third subdivision surface P3, and a fourth subdivision surface P4. A vertical line CTL1 extending in a second direction D2 and a horizontal line CTL2 extending in the first direction D1 may be included on the first bottom surface 111. In an embodiment, the vertical line CTL1 and the horizontal line CTL2 may be a virtual line.

The first bottom surface 111 may be divided into the first subdivision surface P1 and the second subdivision surface P2 on the basis of the horizontal line CTL2. The first subdivision surface P1 and the second subdivision surface P2 may be spaced apart from each other in the second direction D2. The first subdivision surface P1 and the second subdivision surface P2 may be divided from each other on the basis of the horizontal line CTL2.

The first bottom surface 111 may be divided into the first subdivision surface P1 and the third subdivision surface P3 on the basis of the vertical line CTL1. The first subdivision surface P1 and the third subdivision surface P3 may be spaced apart from each other in the first direction D1. The first subdivision surface P1 and the third subdivision surface P3 may be divided from each other on the basis of the vertical line CTL1.

The first bottom surface 111 may be divided into the third subdivision surface P3 and the fourth subdivision surface P4 on the basis of the horizontal line CTL2. The third subdivision surface P3 and the fourth subdivision surface P4 may be spaced apart from each other in the second direction D2. The third subdivision surface P3 and the fourth subdivision surface P4 may be divided from each other on the basis of the horizontal line CTL2.

The first bottom surface 111 may be divided into the second subdivision surface P2 and the fourth subdivision surface P4 on the basis of the vertical line CTL1. The second subdivision surface P2 and the fourth subdivision surface P4 may be spaced apart from each other in the first direction D1. The second subdivision surface P2 and the fourth subdivision surface P4 may be divided from each other on the basis of the vertical line CTL1.

The first signal connection balls B1 to B4 may be provided on the first to fourth subdivision surfaces P1 to P4. The first signal connection balls B1 to B2 on the first subdivision surface P1 may be arranged symmetrically with the first signal connection balls B1 to B2 on the second subdivision surface P2 with respect to the horizontal line CTL2.

In an embodiment, the first signal connection balls B1 to B4 may include first channel balls B1 and second channel balls B2. The first channel balls B1 and second channel balls B2 may be provided on the first subdivision surface P1 and the second subdivision surface P2. The first channel balls B1 may be connected to the first semiconductor chip 201 of the first semiconductor package CH1. The second channel balls B2 may be connected to the second semiconductor chip 202 of the first semiconductor package CH1. The first and second channel balls B1 and B2 on the first subdivision surface P1 and the first and second channel balls B1 and B2 on the second subdivision surface P2 may be symmetric with each other with respect to the horizontal line CTL2.

The first and second channel balls B1 and B2 may each include first to eighth signal balls. For example, the first channel balls B1 may include a first signal ball B1a, a second signal ball B1b, a third signal ball B1c, a fourth signal ball B1d, a fifth signal ball B1e, a sixth signal ball B1f, a seventh signal ball B1g, and an eighth signal ball B1h. Similarly, the second channel balls B2 may include a first signal ball B2a, a second signal ball B2b, a third signal ball B2c, a fourth signal ball B2d, a fifth signal ball B2e, a sixth signal ball B2f, a seventh signal ball B2g, and an eighth signal ball B2h. FIG. 4A illustrates eight signal balls, but the number of signal balls is not limited thereto and may be various. The first to eighth signal balls may each input and output signals and data of a connected semiconductor chip. The first to eighth signal balls may be a data queue (DQ) pin. The same signal balls of different channel balls may input and output the same signal and data. For example, the first signal ball B1a of the first channel balls B1 may input and output the same signal and data as those of the first signal ball B2a of the second channel balls B2.

The first to eighth signal balls connected to the same semiconductor chip may be divided in half and respectively arranged on the first subdivision surface P1 and the second subdivision surface P2. In detail, the first to fourth signal balls B1a, B1b, B1c, and B1d of the first channel balls B1 and the fifth to eighth signal balls B2e, B2f, B2g, and B2h of the second channel balls B2 may be arranged on the first subdivision surface P1. The fifth to eighth signal balls B1e, B1f, B1g, and B1h of the first channel balls B1 and the first to fourth signal balls B2a, B2b, B2c, and B2d of the second channel balls B2 may be arranged on the second subdivision surface P2.

The first channel balls B1 on the first subdivision surface P1 may be arranged symmetrically with the second channel balls B2 on the second subdivision surface P2 with respect to the horizontal line CTL2. For example, the first to fourth signal balls B1a, B1b, B1c, and B1d of the first channel balls B1 on the first subdivision surface P1 may be arranged symmetrically with the first to fourth signal balls B2a, B2b, B2c, and B2d of the second channel balls B2 on the second subdivision surface P2 with respect to the horizontal line CTL2. For example, the first signal ball B1a of the first channel balls B1 may be arranged symmetrically with the first signal ball B2a of the second channel balls B2 with respect to the horizontal line CTL2. In other words, for example, the first signal ball B1a of the first channel balls B1 may be arranged farthest away from the horizontal line CTL2 in the D2 direction and the first signal ball B2a of the second channel balls B2 may be arranged farthest away from the horizontal line CTL2 in the −D2 direction, and the fourth signal ball B1d of the first channel balls B1 may be arranged closest to the horizontal line CTL2 in the D2 direction and the fourth signal ball B2d of the second channel balls B2 may be arranged closest to the horizontal line CTL2 in the −D2 direction, etc.

The second channel balls B2 on the first subdivision surface P1 may be arranged symmetrically with the first channel balls B1 on the second subdivision surface P2 with respect to the horizontal line CTL2. For example, the fifth to eighth signal balls B2e, B2f, B2g, and B2h of the second channel balls B2 on the first subdivision surface P1 may be arranged symmetrically with the fifth to eighth signal balls B1e, B1f, B1g, and B1h of the first channel balls B1 on the second subdivision surface P2 with respect to the horizontal line CTL2. In detail, the fifth signal ball B1e of the first channel balls B1 may be arranged symmetrically with the fifth signal ball B2e of the second channel balls B2 with respect to the horizontal line CTL2. In other words, for example, the eighth signal ball B1h of the first channel balls B1 may be arranged farthest away from the horizontal line CTL2 in the −D2 direction and the eighth signal ball B2h of the second channel balls B2 may be arranged farthest away from the horizontal line CTL2 in the D2 direction, and the fifth signal ball B1e of the first channel balls B1 may be arranged closest to the horizontal line CTL2 in the −D2 direction and the fifth signal ball B2e of the second channel balls B2 may be arranged closest to the horizontal line CTL2 in the D2 direction, etc.

In an embodiment, the first signal connection balls B1 to B4 may include third channel balls B3 and fourth channel balls B4. The first signal connection balls B3 to B4 on the third subdivision surface P3 may be arranged symmetrically with the first signal connection balls B3 to B4 on the fourth subdivision surface P4 with respect to the horizontal line CTL2. The third channel balls B3 and the fourth channel balls B4 may be provided on the third subdivision surface P3 and the fourth subdivision surface P4. The third channel balls B3 may be connected to the third semiconductor chip 203 of the first semiconductor package CH1. The fourth channel balls B4 may be connected to the fourth semiconductor chip 204 of the first semiconductor package CH1. The third and fourth channel balls B3 and B4 on the third subdivision surface P3 and the third and fourth channel balls B3 and B4 on the fourth subdivision surface P4 may be symmetric with each other with respect to the horizontal line CTL2.

The third and fourth channel balls B3 and B4 may each include first to eighth signal balls. For example, the third channel balls B3 may include a first signal ball B3a, a second signal ball B3b, a third signal ball B3c, a fourth signal ball B3d, a fifth signal ball B3e, a sixth signal ball B3f, a seventh signal ball B3g, and an eighth signal ball B3h. Similarly, the fourth channel balls B4 may include a first signal ball B4a, a second signal ball B4b, a third signal ball B4c, a fourth signal ball B4d, a fifth signal ball B4e, a sixth signal ball B4f, a seventh signal ball B4g, and an eighth signal ball B4h. FIG. 4A illustrates eight signal balls. However, the number of signal balls is not limited thereto and may be various. The first to eighth signal balls may each input and output signals and data of a connected semiconductor chip. The first to eighth signal balls may be a data queue (DQ) pin. The same signal balls of different channel balls may input and output the same signal and data. For example, the first signal ball B3a of the third channel balls B3 may input and output the same signal and data as those of the first signal ball B4a of the fourth channel balls B4.

The first to eighth signal balls connected to the same semiconductor chip may be divided in half and respectively arranged on the third subdivision surface P3 and the fourth subdivision surface P4. In detail, the fifth to eighth signal balls B3e, B3f, B3g, and B3h of the third channel balls B3 and the first to fourth signal balls B4a, B4b, B4c, and B4d of the fourth channel balls B4 may be arranged on the third subdivision surface P3. The first to fourth signal balls B3a, B3b, B3c, and B3d of the third channel balls B3 and the fifth to eighth signal balls B4e, B4f, B4g, and B4h of the fourth channel balls B4 may be arranged on the fourth subdivision surface P4.

The fourth channel balls B4 on the third subdivision surface P3 may be arranged symmetrically with the third channel balls B3 on the fourth subdivision surface P4 with respect to the horizontal line CTL2. For example, the first to fourth signal balls B4a, B4b, B4c, and B4d of the fourth channel balls B4 on the third subdivision surface P3 may be arranged symmetrically with the first to fourth signal balls B3a, B3b, B3c, and B3d of the third channel balls B3 on the fourth subdivision surface P4 with respect to the horizontal line CTL2. In detail, the first signal ball B4a of the fourth channel balls B4 may be arranged symmetrically with the first signal ball B3a of the third channel balls B3 with respect to the horizontal line CTL2. In other words, for example, the first signal ball B4a of the fourth channel balls B4 may be arranged farthest away from the horizontal line CTL2 in the D2 direction and the first signal ball B3a of the third channel balls B3 may be arranged farthest away from the horizontal line CTL2 in the −D2 direction, and the fourth signal ball B4d of the fourth channel balls B4 may be arranged closest to the horizontal line CTL2 in the D2 direction and the fourth signal ball B3d of the third channel balls B3 may be arranged closest to the horizontal line CTL2 in the −D2 direction, etc.

The third channel balls B3 on the third subdivision surface P3 may be arranged symmetrically with the fourth channel balls B4 on the fourth subdivision surface P4 with respect to the horizontal line CTL2. For example, the fifth to eighth signal balls B3e, B3f, B3g, and B3h of the third channel balls B3 on the third subdivision surface P3 may be arranged symmetrically with the fifth to eighth signal balls B4e, B4f, B4g, and B4h of the fourth channel balls B4 on the fourth subdivision surface P4 with respect to the horizontal line CTL2. In detail, the fifth signal ball B3e of the third channel balls B3 may be arranged symmetrically with the fifth signal ball B4e of the fourth channel balls B4 with respect to the horizontal line CTL2. In other words, for example, the eighth signal ball B3h of the fourth channel balls B4 may be arranged farthest away from the horizontal line CTL2 in the −D2 direction and the eighth signal ball B3h of the third channel balls B3 may be arranged farthest away from the horizontal line CTL2 in the D2 direction, and the fifth signal ball B4e of the fourth channel balls B4 may be arranged closest to the horizontal line CTL2 in the −D2 direction and the fifth signal ball B3e of the third channel balls B3 may be arranged closest to the horizontal line CTL2 in the D2 direction, etc.

The first signal connection balls on the first subdivision surface P1 may be arranged symmetrically with the first signal connection balls on the third subdivision surface P3 with respect to the vertical line CTL1. The first and second channel balls B1 and B2 on the first subdivision surface P1 and the third and fourth channel balls B3 and B4 on the third subdivision surface P3 may be symmetric with each other with respect to the vertical line CTL1.

The first channel balls B1 on the first subdivision surface P1 may be arranged symmetrically with the fourth channel balls B4 on the third subdivision surface P3 with respect to the vertical line CTL1. For example, the first to fourth signal balls B1a, B1b, B1c, and B1d of the first channel balls B1 on the first subdivision surface P1 may be arranged symmetrically with the first to fourth signal balls B4a, B4b, B4c, and B4d of the fourth channel balls B4 on the third subdivision surface P3 with respect to the vertical line CTL1. In detail, the first signal ball B1a of the first channel balls B1 may be arranged symmetrically with the first signal ball B4a of the fourth channel balls B4 with respect to the vertical line CTL1. In other words, for example, the first signal ball B1a of the first channel balls B1 may be arranged farthest away from the vertical line CTL1 in the −D1 direction and the first signal ball B4a of the fourth channel balls B4 may be arranged farthest away from the vertical line CTL1 in the D1 direction, and the fourth signal ball B1d of the first channel balls B1 may be arranged farthest from the vertical line CTL1 in the −D1 direction and the fourth signal ball B4d of the fourth channel balls B4 may be arranged farthest from the vertical line CTL1 in the D1 direction, etc.

The second channel balls B2 on the first subdivision surface P1 may be arranged symmetrically with the third channel balls B3 on the third subdivision surface P3 with respect to the vertical line CTL1. For example, the fifth to eighth signal balls B2e, B2f, B2g, and B2h of the second channel balls B2 on the first subdivision surface P1 may be arranged symmetrically with the fifth to eighth signal balls B3e, B3f, B3g, and B3h of the third channel balls B3 on the third subdivision surface P3 with respect to the vertical line CTL1. In detail, the fifth signal ball B2e of the second channel balls B2 may be arranged symmetrically with the fifth signal ball B3e of the third channel balls B3 with respect to the vertical line CTL1. In other words, for example, the fifth signal ball B2e of the second channel balls B2 may be arranged closest to the vertical line CTL1 in the −D1 direction and the fifth signal ball B3e of the third channel balls B3 may be arranged closest the vertical line CTL1 in the D1 direction, and the eighth signal ball B2h of the second channel balls B2 may be arranged closest to the vertical line CTL1 in the −D1 direction and the eighth signal ball B3h of the third channel balls B3 may be arranged closest to the vertical line CTL1 in the D1 direction, etc.

The second channel balls B2 on the first subdivision surface P1 may be arranged symmetrically with the fourth channel balls B4 on the third subdivision surface P3 with respect to the vertical line CTL1.

The first signal connection balls on the second subdivision surface P2 may be arranged symmetrically with the first signal connection balls on the fourth subdivision surface P4 with respect to the vertical line CTL1. The first and second channel balls B1 and B2 on the second subdivision surface P2 and the fourth and third channel balls B4 and B3 on the fourth subdivision surface P4 may be symmetric with each other with respect to the vertical line CTL1.

The first channel balls B1 on the second subdivision surface P2 may be arranged symmetrically with the fourth channel balls B4 on the fourth subdivision surface P4 with respect to the vertical line CTL1. For example, the fifth to eighth signal balls B1e, B1f, B1g, and B1h of the first channel balls B1 on the second subdivision surface P2 may be arranged symmetrically with the fifth to eighth signal balls B4e, B4f, B4g, and B4h of the fourth channel balls B4 on the fourth subdivision surface P4 with respect to the vertical line CTL1. In detail, the fifth signal ball B1e of the first channel balls B1 may be arranged symmetrically with the fifth signal ball B4e of the fourth channel balls B4 with respect to the vertical line CTL1. In other words, for example, the fifth signal ball B1e of the first channel balls B1 may be arranged closest to the vertical line CTL1 in the −D1 direction and the fifth signal ball B4e of the fourth channel balls B4 may be arranged closest the vertical line CTL1 in the D1 direction, and the eighth signal ball B1h of the first channel balls B1 may be arranged closest to the vertical line CTL1 in the −D1 direction and the eighth signal ball B4h of the fourth channel balls B4 may be arranged closest to the vertical line CTL1 in the D1 direction, etc.

The second channel balls B2 on the second subdivision surface P2 may be arranged symmetrically with the third channel balls B3 on the fourth subdivision surface P4 with respect to the vertical line CTL1. For example, the first to fourth signal balls B2a, B2b, B2c, and B2d of the second channel balls B2 on the second subdivision surface P2 may be arranged symmetrically with the first to fourth signal balls B3a, B3b, B3c, and B3d of the third channel balls B3 on the fourth subdivision surface P4 with respect to the vertical line CTL1. In detail, the first signal ball B2a of the second channel balls B2 may be arranged symmetrically with the first signal ball B3a of the third channel balls B3 with respect to the vertical line CTL1. In other words, for example, the first signal ball B2a of the second channel balls B2 may be arranged farthest away from the vertical line CTL1 in the −D1 direction and the first signal ball B3a of the third channel balls B3 may be arranged farthest away from the vertical line CTL1 in the D1 direction, and the fourth signal ball B2d of the second channel balls B2 may be arranged farthest from the vertical line CTL1 in the −D1 direction and the fourth signal ball B3d of the third channel balls B3 may be arranged farthest from the vertical line CTL1 in the D1 direction, etc.

For another example, the first channel balls B1 on the second subdivision surface P2 may be arranged symmetrically with the third channel balls B3 on the fourth subdivision surface P4 with respect to the vertical line CTL1. The second channel balls B2 on the second subdivision surface P2 may be arranged symmetrically with the fourth channel balls B4 on the fourth subdivision surface P4 with respect to the vertical line CTL1.

According to various embodiments, signal connection balls connected to the first and second semiconductor packages CH1 and CH2 may be provided on each of the first to fourth subdivision surfaces P1 to P4 and may be arranged symmetrically with each other with respect to the vertical line CTL1 and the horizontal line CTL2. Here, signal balls that process the same signal and data, among the first to fourth channel balls B1 to B4, may be arranged symmetrically with each other. For example, the first signal ball B1a of the first channel balls B1 may be arranged symmetrically with the first signal ball B4a of the fourth channel balls B4 with respect to the vertical line CTL1 and may be arranged symmetrically with the first signal ball B2a of the second channel balls B2 with respect to the horizontal line CTL2. Accordingly, when the first semiconductor package CH1 and the second semiconductor package CH2 are respectively provided on both sides of the module substrate 400, signal balls that process the same signal and data may be arranged facing each other.

In detail, referring back to FIG. 3, the first to fourth signal balls B1a, B1b, B1c, and B1d of the first channel balls B1 of the first semiconductor package CH1 may be arranged so as to face the first to fourth signal balls B2a, B2b, B2c, and B2d of the second channel balls B2 of the second semiconductor package CH2. The first to fourth signal balls B2a, B2b, B2c, and B2d of the second channel balls B2 of the first semiconductor package CH1 may be arranged so as to face and vertically align with the first to fourth signal balls B1a, B1b, B1c, and B1d of the first channel balls B1 of the second semiconductor package CH2 in the D3 direction.

The first signal connection balls may be connected to corresponding second signal connection balls. In detail, signal balls facing each other with the module substrate 400 therebetween may be connected to each other by a signal line 70. The first signal connection balls on the first semiconductor package CH1 may be connected to the second signal connection balls of the second semiconductor package CH2 by the signal line 70. Since signal balls that process the same signal and data are arranged facing each other, a length of the signal line 70 for connecting the signal balls may decrease. For example, in some embodiments, the first signal connection balls of the first semiconductor package CH1 may be connected to corresponding ones of the second signal connection balls of the second semiconductor package CH2 by the signal lines 70, and each of the first signal connection balls of the first semiconductor package CH1 may be arranged vertically aligned with the corresponding one of the second signal connection balls of the second semiconductor package CH2 to which the first signal connection ball is connected. Furthermore, since a signal swap between the first and second signal connection balls is skipped, interference of electrical signals may reduce and quality of electrical signals may be improved. The signal swap may refer to a process of swapping signals of signal balls that process the same signal and data when the signal balls are arranged misaligned without facing each other. Furthermore, since passive elements provided on the module substrate 400 are omitted, integration of a semiconductor memory module may be improved. As a result, electrical characteristics and reliability of the semiconductor memory module according to the inventive concept may be improved.

FIGS. 4B and 4C are plan views for describing the first semiconductor package of FIG. 2 according to some embodiments. Detailed descriptions on technical features that overlap with the technical features described above with reference to FIG. 4A are omitted for conciseness, and differences will be described in detail.

Regarding FIGS. 4B and 4C, differential signal balls DBxy may be further included between the first semiconductor package CH1 and the module substrate 400 and between the second semiconductor package CH2 and the module substrate 400. The differential signal balls may be an input or output pin used for transmitting differential signals.

For example, the differential signal balls DBxy may be provided on the first bottom surface 111 of the first semiconductor package CH1. First to fourth differential signal balls may be provided on each of the first to fourth subdivision surfaces P1 to P4. For example, a first differential signal ball DB1a, a second differential signal ball DB1b, a third differential signal ball DB1c, and a fourth differential signal ball DB1d may be provided on the first subdivision surface P1. Similarly, a first differential signal ball DB2a, a second differential signal ball DB2b, a third differential signal ball DB2c, and a fourth differential signal ball DB2d may be provided on the second subdivision surface P2, and so on. The first to fourth differential signal balls may transmit different differential signals. Although the first to fourth differential signals balls are illustrated in the drawings, the number of differential signal balls may be various.

The first differential signal balls DB1a, DB2a, DB3a, and DB4a may input and output a data strobe signal DQS, the second differential signal balls DB1b, DB2b, DB3b, and DB4b may input and output a data strobe bar signal DQSB. The third differential signal balls DB1c, DB2c, DB3c, and DB4c may input and output a read enable signal RE, and the fourth differential signal balls DB1d, DB2d, DB3d, and DB4d may input and output a read enable bar signal REB.

The first to fourth differential signal balls DB1a, DB1b, DB1c, and DB1d on the first subdivision surface P1 may be connected to the first semiconductor chip 201. The first to fourth differential signal balls DB2a, DB2b, DB2c, and DB2d on the second subdivision surface P2 may be connected to the second semiconductor chip 202. The first to fourth differential signal balls DB3a, DB3b, DB3c, and DB3d on the third subdivision surface P3 may be connected to the third semiconductor chip 203. The first to fourth differential signal balls DB4a, DB4b, DB4c, and DB4d on the fourth subdivision surface P4 may be connected to the fourth semiconductor chip 204.

The differential signal balls on the first subdivision surface P1 may be arranged symmetrically with the differential signal balls on the second subdivision surface P2 with respect to the horizontal line CTL2. For example, the first differential signal ball DB1a on the first subdivision surface P1 may be arranged symmetrically with the first differential signal ball DB2a on the second subdivision surface P2 with respect to the horizontal line CTL2.

The differential signal balls on the third subdivision surface P3 may be arranged symmetrically with the differential signal balls on the fourth subdivision surface P4 with respect to the horizontal line CTL2. For example, the third differential signal ball DB3c on the third subdivision surface P3 may be arranged symmetrically with the third differential signal ball DB4c on the fourth subdivision surface P4 with respect to the horizontal line CTL2.

The differential signal balls on the first subdivision surface P1 may be arranged symmetrically with the differential signal balls on the third subdivision surface P3 with respect to the vertical line CTL1. For example, the second differential signal ball DB1b on the first subdivision surface P1 may be arranged symmetrically with the second differential signal ball DB3b on the third subdivision surface P3 with respect to the vertical line CTL1.

The differential signal balls on the second subdivision surface P2 may be arranged symmetrically with the differential signal balls on the fourth subdivision surface P4 with respect to the vertical line CTL1. For example, the fourth differential signal ball DB2d on the second subdivision surface P2 may be arranged symmetrically with the fourth differential signal ball DB4d on the fourth subdivision surface P4 with respect to the vertical line CTL1.

Referring to FIG. 4C, in an embodiment, the first and second signal connection balls on the first to fourth subdivision surfaces P1 to P4 may be variously arranged. In other words, the first to fourth signal balls may not be arranged in a line along the second direction D2 as illustrated in FIG. 4A. The first and second signal connection balls may be arranged according to arrangement of the semiconductor dies 200 in the first and second semiconductor packages CH1 and CH2. For example, in an embodiment, the first to fourth signal balls B1a, B1b, B1c, and B1d of the first channel balls B1 on the second subdivision surface P2 may be arranged spaced apart from each other in the first direction D1 and the second direction D2. Furthermore, any one of signal balls of the second channel balls B2 may be arranged between the first to fourth signal balls B1a, B1b, B1c, and B1d of the first channel balls B1.

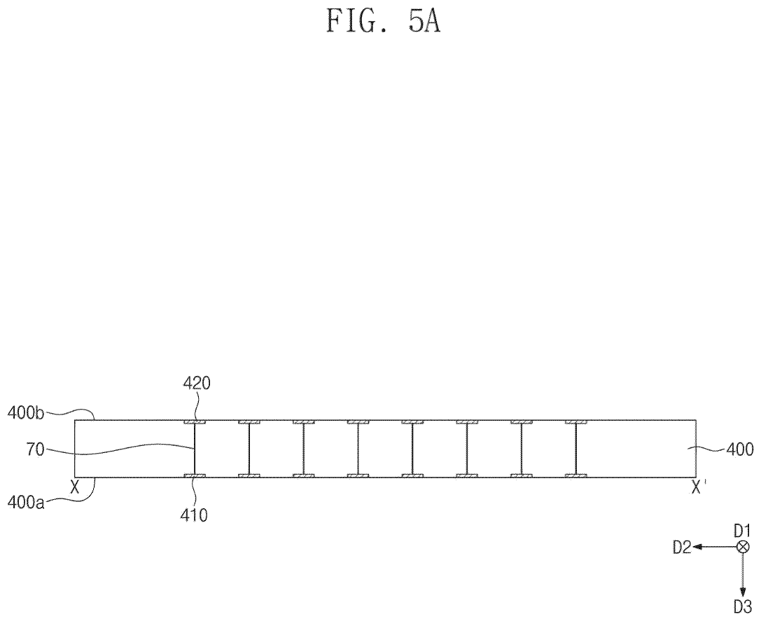

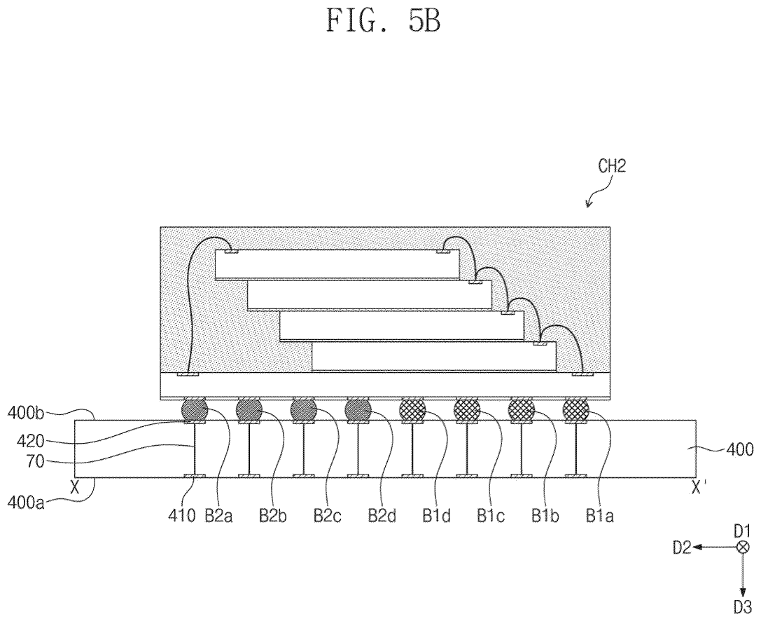

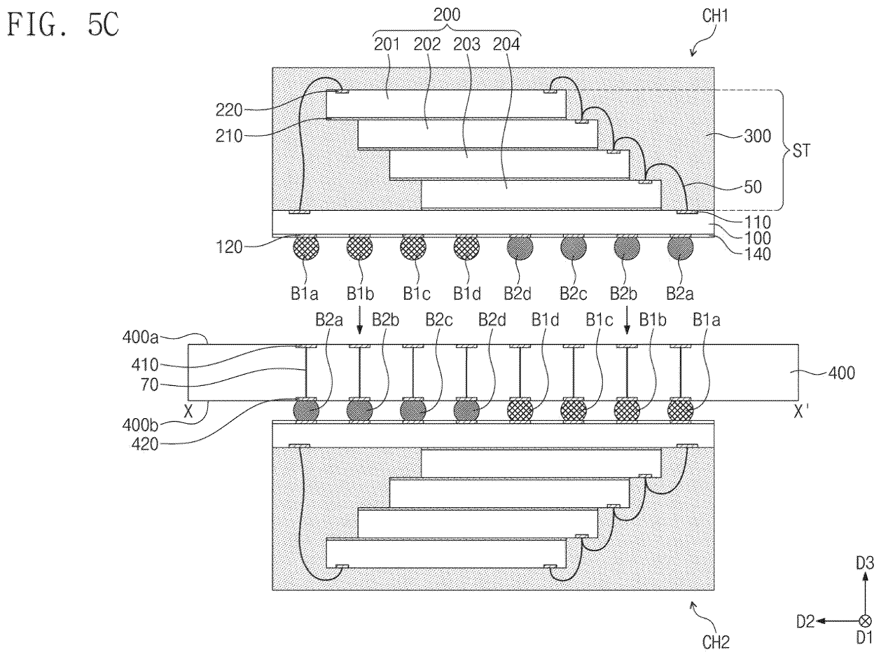

FIGS. 5A, 5B, and 5C are cross-sectional views for describing a method of manufacturing a semiconductor memory module according to embodiments. FIGS. 5A, 5B, and 5C are cross-sectional view taken along line A-A′ of FIG. 2.

Referring to FIG. 5A, the module substrate 400 may be provided. The first conductive pads 410 may be formed on the first side 400a of the module substrate 400, and the second conductive pads 420 may be formed on the second side 400b. Signal lines 70 extending in the third direction D3 may be formed in the module substrate 400. The signal lines 70 may connect the first conductive pad 410 and the second conductive pad 420 which correspond to each other. A length of the signal line 70 may be equal to or less than a thickness of the module substrate 400 in the third direction D3.

Referring to FIG. 5B, second signal connection balls may be formed on the second side 400b of the module substrate 400. The second signal connection balls may be respectively formed on the second conductive pads 420 of the module substrate 400. The second semiconductor package CH2 may be mounted on the second side 400b of the module substrate 400. The second signal connection balls may be bonded to the second conductive pads 420 through a reflow process.

Referring to FIGS. 3 and 5C, the first side 400a of the module substrate 400 may be exposed by turning the structure of FIG. 5B upside down. First signal connection balls may be provided on the first side 400a of the module substrate 400. The first signal connection balls may be respectively formed on the first conductive pads 410 of the module substrate 400. The first semiconductor package CH1 may be mounted on the first side 400a of the module substrate 400. The first signal connection balls may be bonded to the first conductive pads 410 through a reflow process.

Since signal connection balls of semiconductor packages are arranged facing each other in the semiconductor memory module according to various embodiments, electrical signal interference between the semiconductor packages may reduce and a signal transfer speed may be improved. Furthermore, since a signal swap between the semiconductor packages is skipped, the quality of electrical signals may be improved, and passive elements on a substrate may be omitted. As a result, electrical characteristics and reliability of the semiconductor memory module according to various embodiments may be improved.

Although various embodiments have been described with reference to the drawings, it is understood that the present disclosure should not be limited to these embodiments but various changes and modifications can be made by one ordinary skilled in the art within the spirit and scope as set forth in the appended claims.

What is claimed is:

1. A semiconductor memory module comprising:
a substrate including a first side and a second side opposing the first side;
a first semiconductor package on the first side, the first semiconductor package including a first bottom surface facing the first side; and
first signal connection balls between the first side and the first bottom surface,
wherein the first bottom surface includes a first subdivision surface, and a second subdivision surface divided from the first subdivision surface based on a horizontal line extending in a first direction, and
wherein the first signal connection balls on the first subdivision surface and the first signal connection balls on the second subdivision surface are arranged symmetrically with each other with respect to the horizontal line.

2. The semiconductor memory module of claim 1,
wherein the first semiconductor package includes a first semiconductor chip and a second semiconductor chip,
wherein the first signal connection balls include:
first channel balls connected to the first semiconductor chip; and
second channel balls connected to the second semiconductor chip, and
wherein the first channel balls and the second channel balls are arranged on each of the first subdivision surface and the second subdivision surface.

3. The semiconductor memory module of claim 2, wherein the first channel balls on the first subdivision surface are arranged symmetrically with the second channel balls on the second subdivision surface with respect to the horizontal line.

4. The semiconductor memory module of claim 2, wherein the second channel balls on the first subdivision surface are arranged symmetrically with the first channel balls on the second subdivision surface with respect to the horizontal line.

5. The semiconductor memory module of claim 1,
wherein the first subdivision surface and the second subdivision surface each further include a differential signal ball, and
wherein the differential signal ball on the first subdivision surface and the differential signal ball on the second subdivision surface are arranged symmetrically with each other with respect to the horizontal line.

6. The semiconductor memory module of claim 1,
wherein the first bottom surface further includes a third subdivision surface,
wherein the third subdivision surface is divided from the first subdivision surface based on a vertical line,
wherein the vertical line extends in a second direction intersecting the first direction, and
wherein the first signal connection balls on the first subdivision surface and the first signal connection balls on the third subdivision surface are arranged symmetrically with each other with respect to the vertical line.

7. The semiconductor memory module of claim 6,
wherein the first bottom surface further includes a fourth subdivision surface,
wherein the fourth subdivision surface is divided from the third subdivision surface based on the horizontal line, and
wherein the first signal connection balls on the fourth subdivision surface are arranged symmetrically with the first signal connection balls on the third subdivision surface with respect to the horizontal line.

8. The semiconductor memory module of claim 7,
wherein the first semiconductor package includes a third semiconductor chip and a fourth semiconductor chip,
wherein the first signal connection balls include:
third channel balls connected to the third semiconductor chip; and
fourth channel balls connected to the fourth semiconductor chip, and
wherein the third channel balls and the fourth channel balls are arranged on each of the third subdivision surface and the fourth subdivision surface.

9. The semiconductor memory module of claim 6,
wherein the first bottom surface further includes a fourth subdivision surface,
wherein the fourth subdivision surface is divided from the second subdivision surface based on the vertical line, and
wherein the first signal connection balls on the fourth subdivision surface are arranged symmetrically with the first signal connection balls on the second subdivision surface with respect to the vertical line.

10. The semiconductor memory module of claim 6,
wherein the first subdivision surface and the third subdivision surface each further include a differential signal ball, and
wherein the differential signal ball on the first subdivision surface and the differential signal ball on the third subdivision surface are arranged symmetrically with each other with respect to the vertical line.

11. The semiconductor memory module of claim 1, further comprising:
a second semiconductor package on the second side of the substrate, the second semiconductor package including a second bottom surface facing the second side; and
second signal connection balls interposed between the second side and the second bottom surface.

12. The semiconductor memory module of claim 11,
wherein the first signal connection balls are connected to corresponding ones of the second signal connection balls, and
wherein each of the first signal connection balls are arranged vertically aligned with the corresponding one of the second signal connection balls to which the first signal connection ball is connected.

13. A semiconductor memory module comprising:
a substrate including a first side a second side opposing the first side;
a first semiconductor package on the first side, the first semiconductor package including a first bottom surface facing the first side; and
first signal connection balls interposed between the first side and the first bottom surface,
wherein the first bottom surface includes a first subdivision surface, and a second subdivision surface that is divided from the first subdivision surface based on a horizontal line extending in a first direction,
wherein the first semiconductor package includes a first semiconductor chip and a second semiconductor chip,
wherein the first signal connection balls include:
first channel balls connected to the first semiconductor chip; and
second channel balls connected to the second semiconductor chip, and
wherein the first channel balls on the first subdivision surface are arranged symmetrically with the second channel balls on the second subdivision surface with respect to the horizontal line.

14. The semiconductor memory module of claim 13, wherein the second channel balls on the first subdivision surface are arranged symmetrically with the first channel balls on the second subdivision surface with respect to the horizontal line.

15. The semiconductor memory module of claim 13,
wherein the first subdivision surface and the second subdivision surface each further include a differential signal ball, and
wherein the differential signal ball on the first subdivision surface and the differential signal ball on the second subdivision surface are arranged symmetrically with each other with respect to the horizontal line.

16. A semiconductor memory module comprising:
a substrate including a first side and a second side opposing the first side;
a first semiconductor package on the first side, the first semiconductor package including a first bottom surface facing the first side;
a second semiconductor package on the second side of the substrate, the second semiconductor package including a second bottom surface facing the second side;
first signal connection balls interposed between the first side and the first bottom surface; and
second signal connection balls interposed between the second side and the second bottom surface,
wherein the first bottom surface includes:
a first subdivision surface and a second subdivision surface that is divided from of the first subdivision surface based on a horizontal line extending in a first direction; and
a third subdivision surface divided from the first subdivision surface based on a vertical line extending in a second direction intersecting the first direction,
wherein the first signal connection balls on the first subdivision surface and the first signal connection balls on the second subdivision surface are arranged symmetrically with each other with respect to the horizontal line, and
wherein the first signal connection balls on the first subdivision surface and the first signal connection balls on the third subdivision surface are arranged symmetrically with each other with respect to the vertical line.

17. The semiconductor memory module of claim 16,
wherein the first subdivision surface and the second subdivision surface each further include a differential signal ball, and
wherein the differential signal ball on the first subdivision surface and the differential signal ball on the second subdivision surface are arranged symmetrically with each other with respect to the horizontal line.

18. The semiconductor memory module of claim 16,
wherein the first bottom surface further includes a fourth subdivision surface,
wherein the fourth subdivision surface is divided from the third subdivision surface based on the horizontal line, and
wherein the first signal connection balls on the fourth subdivision surface are arranged symmetrically with the first signal connection balls on the third subdivision surface with respect to the horizontal line.

19. The semiconductor memory module of claim 16,
wherein the first bottom surface further includes a fourth subdivision surface,
wherein the fourth subdivision surface is divided from the second subdivision surface based on the vertical line, and
wherein the first signal connection balls on the fourth subdivision surface are arranged symmetrically with the first signal connection balls on the second subdivision surface with respect to the vertical line.

20. The semiconductor memory module of claim 16,
wherein the first signal connection balls are connected to corresponding ones of the second signal connection balls, and
wherein each of the first signal connection balls are arranged vertically aligned with the corresponding one of the second signal connection balls to which the first signal connection ball is connected.
